(19) United States
(12) Patent Application Publication
(10) Pub. No.: US 2024/0242946 A1
(43) Pub. Date: Jul. 18, 2024

(54) LOW POWER PLASMA SYSTEM MONITOR METHOD

(71) Applicant: SKY TECH INC., Hsinchu County (TW)

(72) Inventors: JING-CHENG LIN, Hsinchu County (TW); JUNG-HUA CHANG, Hsinchu County (TW)

(21) Appl. No.: 18/098,131

(22) Filed: Jan. 18, 2023

(51) Int. Cl. H01J 37/32; G01B 11/06; G01N 27/04; H01L 21/66

(52) U.S. Cl. CPC H01J 37/3299; G01B 11/06; G01N 27/04; H01L 22/12; H01J 2237/24592; H01J 2237/3323; H01L 29/7786

(57) ABSTRACT

This disclosure is a low power plasma system monitor method, which can be used to monitor the uniformity of the low power plasma system. A deposition process is performed on a testing substrate to form a metal film on the testing substrate. The resistance of the metal film on the testing substrate is measured to generate a plurality of first sheet resistance values. A testing pretreatment process is performed on the testing substrate through the low power plasma system to form a testing passivation on the metal film of the testing substrate. The resistance of the testing substrate after the testing pretreatment process is measured to generate a plurality of second sheet resistance values. Then the first sheet resistance values and the second sheet resistance values are analyzed to know the uniformity of the low power plasma system.

### BACKGROUND

### Technical Field

This disclosure is a low power plasma system monitor method, which is able to quickly and accurately know the uniformity and stability of the low power plasma system.

### Related Art

At present, the process technology of silicon material is very mature, and has the advantage of low cost, and is widely used in various electronic products. For example, Metal-Oxide-Semiconductor Field-Effect Transistor (MOSFET) is widely used in various digital circuits and analog circuits.

However, MOSFET includes doped impurities that cause electron mobility of the MOSFET to be limited. In contrast, a high electron mobility transistor (HEMT) comprises incorporating a heterojunction between two materials with different band gaps. For example, HMET includes an adjacent doped wide band material and an undoped narrow band gap material, and a two-dimensional electron gas (2DEG) is formed at the heterojunction therebetween.

2DEG has high mobility electrons and low on-state resistances, so that HEMT is able to operate at higher frequency, and is used in high-frequency products such as cell phones, satellite television receivers, voltage converters, and radar equipment.

### SUMMARY

This disclosure provides a novel low power plasma system monitor method, which can accurately monitor the uniformity and/or the stability of the low power plasma system. After confirming that the stability and/or the uniformity of the low power plasma system reaches a preset value, the low power plasma system performs a pretreatment process on the surface of a barrier, a gate material and/or a separating layer of HEMT to repair dangling bonds, and is conducive to increase the yield and quality of HEMT.

The low power plasma system monitor method of this disclosure firstly measures the sheet resistances of a testing substrate having a metal film to generate a plurality of first sheet resistance values. Then, a testing pretreatment process is performed on the testing substrate with the metal film through the low power plasma system to form a testing passivation on the surface of the metal film.

The sheet resistances of the stacked metal film and testing passivation on the testing substrate are measured to generate a plurality of second sheet resistance values. The thickness of the testing passivation can be estimated from the difference between the first sheet resistances and the second sheet resistances to determine uniformity of the testing passivation and the low power plasma system. After determining that the uniformity and/or stability of the low power plasma system have met the requirements, the low power plasma system can be used to perform a pretreatment process on the barrier, the gate material and/or the separating layer of HEMT.

To achieve the object, this disclosure provides a low power plasma system monitor method, comprising: providing a testing substrate, wherein a surface of the testing substrate has a metal film; measuring sheet resistances of the metal film on the testing substrate, and generating a plurality of first sheet resistance values; performing a testing pretreatment process on the metal film of the testing substrate by a low power plasma system, and forming a testing passivation on the metal film; measuring the sheet resistances of the testing passivation on the testing substrate, and generating a plurality of second sheet resistance values; and analyzing the first sheet resistance values and the second sheet resistance values to obtain uniformity of the low power plasma system.

### BRIEF DESCRIPTION OF THE DRAWINGS

This disclosure will become more fully understood from the detailed description given herein below for illustration only, and thus not limitative of this disclosure, wherein:

FIG. 1 is a flow chart of a low power plasma system monitor method according to an embodiment of this disclosure.

FIG. 2 to FIG. 6 are schematic diagrams of HEMT manufacturing process according to an embodiment of this disclosure.

FIG. 7 is a top view of testing substrate according to an embodiment of this disclosure.

FIG. 8 is a flow chart of a low power plasma system monitor method according to another embodiment of this disclosure.

### DETAILED DESCRIPTION

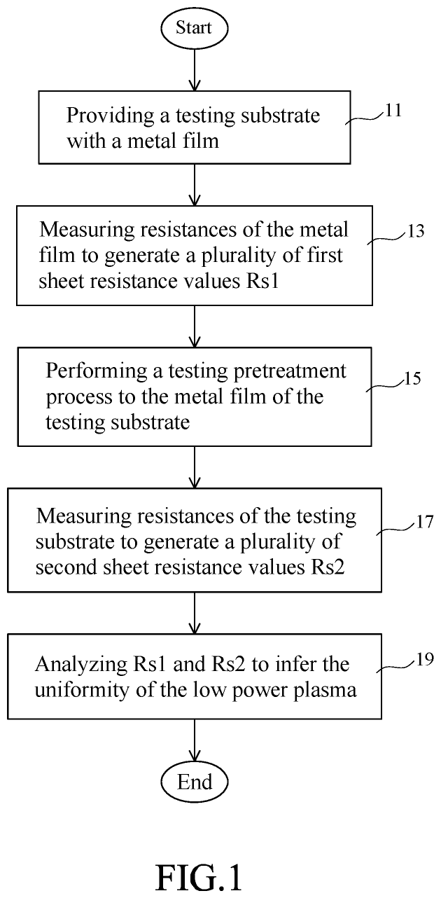

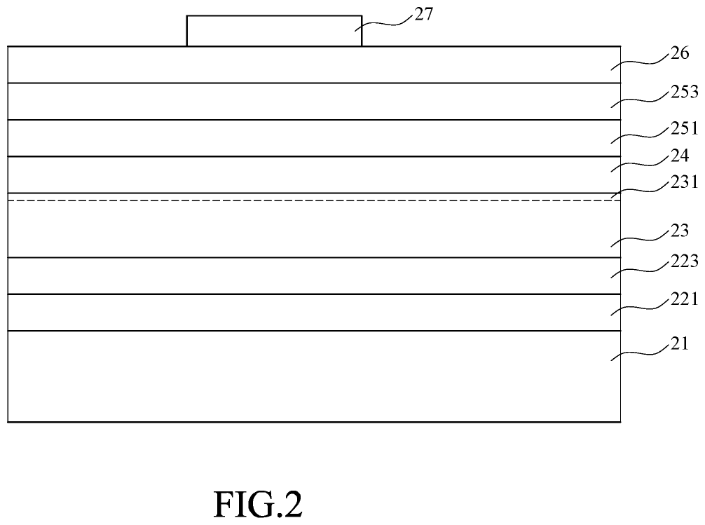

FIG. 1 is a flow chart of a low power plasma system monitor method according to an embodiment of this disclosure. FIG. 2 to FIG. 6 are schematic diagrams of a HEMT manufacturing process according to an embodiment of this disclosure. As shown in FIG. 2 to FIG. 6, a substrate 21 is provided. For example, the substrate 21 may be a silicon substrate, a silicon carbide substrate or a sapphire substrate, and a channel 23 can be formed on the substrate 21 in the subsequent manufacturing process.

The material of the channel 23 and the substrate 21 are very different in lattice constant and coefficient of thermal expansion (CTE). If the channel 23 is directly grown on the surface of the substrate 21, it will cause lattice mismatch and defects between the channel 23 and the substrate 21, thereby affecting the quality and yield of the HEMT.

In order to avoid the above-mentioned problems, a nuclear layer 221 (or seed layer) and a buffer 223 may be sequentially formed on the surface of the substrate 21 to over in lattice mismatch and coefficient of thermal expansion between the channel 23 and the substrate 21. It is one embodiment of this disclosure to sequentially form the nuclear layer 221 and the buffer 223 on the surface of the substrate 21, and is not a limitation of the invention. In other embodiments of this disclosure, the nuclear layer 221 may be omitted.

In one embodiment of the invention, the nuclear layer 221 is firstly formed on the surface of the substrate 21. For example, the nuclear layer 221 may be aluminum nitride (AlN). Then the buffer 223 is formed on the nuclear layer 221. For example, the buffer 223 may be aluminum gallium nitride (AlxGa(1-x)N, 0<x<1), and AlGaN may be a multi-layer structure, wherein the x value of AlxGa(1-x)N decreases from the substrate 21 toward the channel 23.

The channel 23 is formed above the buffer 223, and a barrier 24 is formed above the channel 23. For example, the channel 23 may include gallium nitride (GaN), aluminum gallium nitride (AlGaN), indium gallium nitride (InGaN) or aluminum indium gallium nitride (InAlGaN), etc., the barrier 24 may include aluminum nitride or aluminum gallium nitride (AlyGa(1-y)N, 0<y<1). In one embodiment of this disclosure, the channel 23 and the barrier 24 may be sequentially formed on the buffer 223 by metal organic chemical vapor deposition (MOCVD).

The heterojunction between the barrier 24 and the channel 23 confines electrons to a triangular quantum well to form a two-dimensional electron gas (2DEG) 231.

A separating layer 251 may be formed above the barrier 24, and then a gate material 253 may be formed on the separating layer 251. For example, the metal-semiconductor formed Schottky Contact is used to make a Schottky gate, wherein the separating layer 251 may be p-type gallium nitride (GaN), and the gate material 253 may be titanium nitride (TiN).

In addition, a protective layer 26 may be formed above the gate material 253, and then a photolithography process is performed to form a photoresist 27 on a partial area of the protective layer 26 or the gate material 253, and defines a disposition area of the gate material 253.

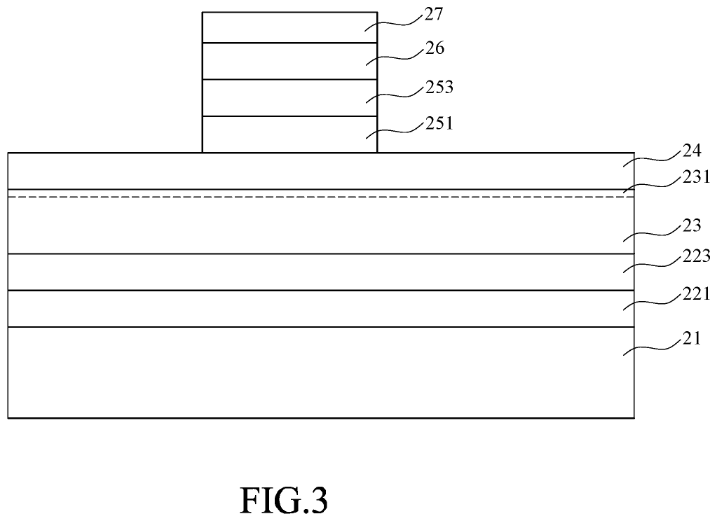

As shown in FIG. 3, an etching process is performed, and the protective layer 26, the gate material 253, the separating layer 251 and/or a partial of the barrier 24 without covering by the photoresist 27 will be removed.

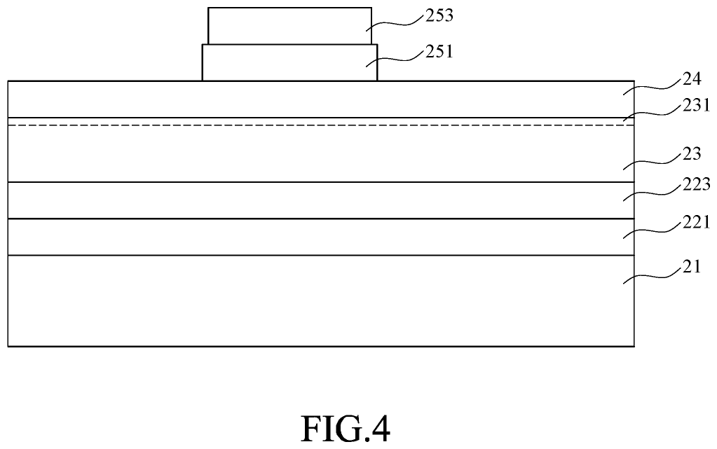

As shown in FIG. 4, after completing the etching process, the protective layer 26 and the photoresist 27 above the gate material 253 will be removed in sequence. Defects may be formed on the surface of the barrier 24, the gate material 253 and/or the separating layer 251 after the etching process. For example, dangling bonds may be formed on the surface of the barrier 24, thereby affecting the performance of HEMT 20.

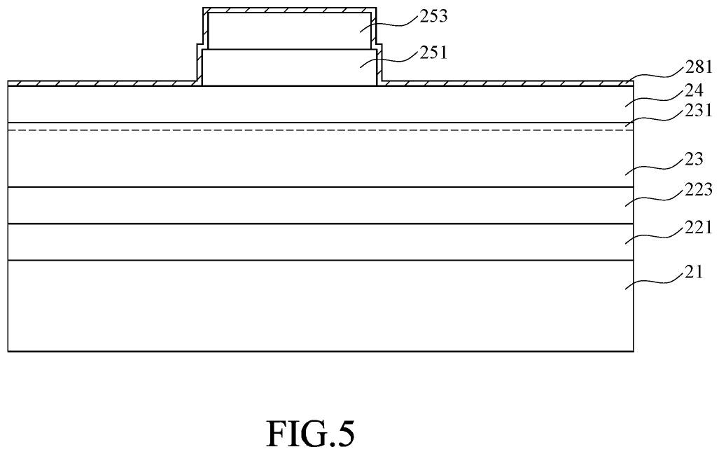

As shown in FIG. 5, after removing the photoresist 27 and the protective layer 26, a low power plasma system can be used to perform a pretreatment process on the surface of the barrier 24, the gate material 253 and/or the separating layer 251 to repair dangling bonds on the surface of the barrier 24, the gate material 253 and/or the separating layer 251. For example, the power of the low power plasma system may be less than 50 W. Then, an ALD process is performed to form a passivation 281 on the surface of the barrier 24, the gate material 253 and/or the separating layer 251.

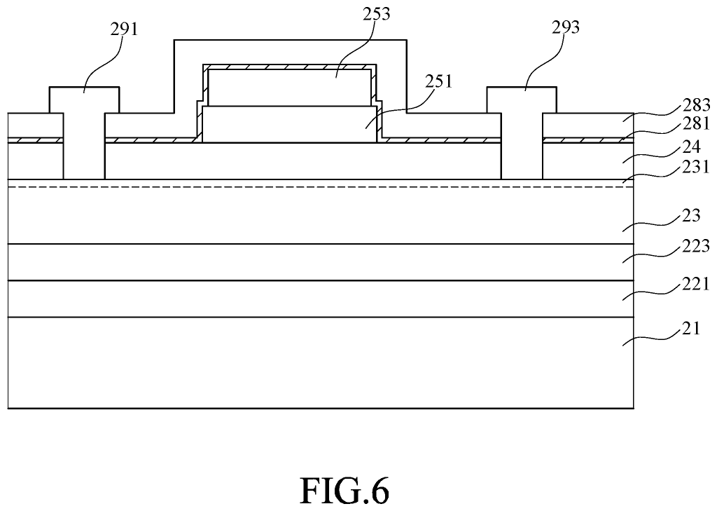

As shown in FIG. 6, after forming the passivation 281, an insulating layer 283 may be formed on the surface of the passivation 281. A partial area of the insulating layer 283, the passivation 281 and the barrier 24 is removed by etching process to form a plurality of etched areas, and then a source material 291 and a drain material 293 will be formed in the etched areas of the insulation layer 283, the passivation 281 and the barrier 24 to be connected to the channel 23.

The uniformity and stability of the low power plasma, and the uniformity, step coverage and thickness of the passivation 281 formed by the ALD process will greatly affect the characteristics of the HEMT 20.

After confirming that the uniformity of the low power plasma system has reached a preset value, the pretreatment process is performed to repair dangling bonds on the surface of the barrier 24, gate material 253 and/or the separating layer 251 through the low power plasma system, which will improve the quality of HEMT 20.

Generally, plasma stickers or plasma indicators may be attached to a partial area of the testing substrate, and the testing pretreatment process is performed on the testing substrate and the plasma indicator. The color of the plasma sticker changes can be used to judge the status of the low power plasma system. However, the color of the plasma indicator cannot tell the overall uniformity of the low power plasma system.

Thus, this disclosure proposes a low power plasma system monitor method, which can accurately determine whether the uniformity and/or the stability of the low power plasma system has met the preset value, and can greatly reduce the cost of monitor process. As shown in FIG. 1, a testing substrate 31 is provided, wherein the surface of the testing substrate 31 has a metal film, as step 11.

In one embodiment of the invention, the testing substrate 31 may be a wafer, and a deposition process is performed on the testing substrate 31 to form the metal film on the surface of the testing substrate 31. For example, the metal film may be a titanium film. The metal film is a titanium film is only one embodiment of the invention, and is not a limitation of the invention. In practical applications, the metal film needs to react with the low power plasma.

In actual application, the thickness of the metal film is preferably less than 100 Angstroms (Å). Basically, if the metal film is too thick, it is difficult to accurately measure the sheet resistance value. If the metal film is too thin, the thickness of the metal film is often uneven, which is not conducive to accurately judging whether the low power plasma system is uniform.

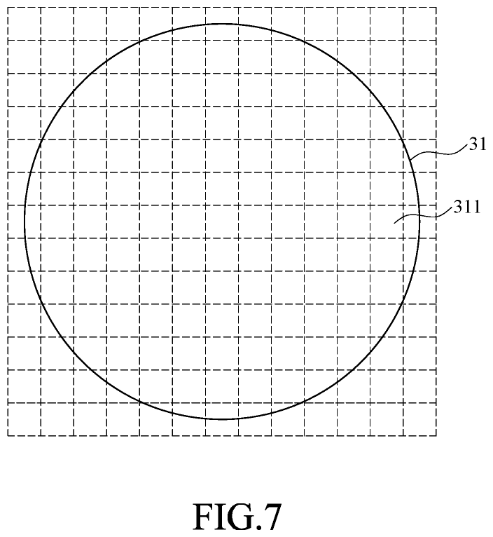

The resistance of the metal film on the surface of the testing substrate 31 can be measured through a sheet resistance measuring instrument, as shown in step 13. As shown in FIG. 7, the surface of the testing substrate 31 may be divided into a plurality of regions 311, and the sheet resistance of the metal film in each region 311 is measured respectively to generate a plurality of first sheet resistance values Rs1.

A testing substrate 31 with the metal film is placed in a chamber, and a testing pretreatment process is performed to the metal film on the surface of the testing substrate 31 through a low power plasma system to form a testing passivation on the surface of the metal film of the testing substrate 31, as step 15. For example, the process conditions of the low power plasma system performing the testing pretreatment process may be: nitrogen gas with a gas flow rate of 50 sccm, power less than 50 W and pretreatment time of 30 minutes, and a testing passivation of titanium nitride is formed on the surface of the titanium film. The gas flow rate, power and pretreatment time of the above-mentioned low power plasma system are only one embodiment of the invention, and are not limitations the invention.

In actual application, an interval time between completing the deposition of the metal film on the testing substrate 31 and performing the testing pretreatment process on the metal film of the testing substrate may be less than a threshold value. For example, the interval time may be less than 4 hours. This is to prevent the metal film deposited on the testing substrate 31 from being oxidized, thereby affecting the accuracy of the low power plasma system monitor method of the invention.

After completing the testing pretreatment process on the metal film of the testing substrate 31, the testing substrate 31 will be taken out of the chamber, and then the sheet resistance measuring instrument measures the resistance of stacked metal film and testing passivation in each region 311 to generate a plurality of second sheet resistance values Rs2, as step 17. In one embodiment of the invention, the number of the first sheet resistance values Rs1 and that of the second sheet resistance values Rs2 are the same.

By analyzing the first sheet resistance values Rs1 and the second sheet resistance values Rs2, the thickness and uniformity of the testing passivation on the metal film can be known, and then the uniformity of the low power plasma system can be inferred, as shown in step 19.

In one embodiment of the invention, the difference between the second sheet resistance value Rs2 and the first sheet resistance value Rs1 of each region 311 of the testing substrate 31 can be calculated to obtain a difference sheet resistance value Rsd of each region 311 of the testing substrate 31. According to the difference sheet resistance value Rsd of each region 311 of the testing substrate 31, the thickness and uniformity of the testing passivation on each region 311 of the testing substrate 31 can be respectively inferred, and further obtained the uniformity of low power plasma system.

In actual application, the difference sheet resistance values Rsd of all regions 311 can be compared with each other, or a sheet resistance distribution diagram of the testing substrate 31 can be made to determine whether the uniformity of the testing passivation and low power plasma system meets the preset value.

After determining that the uniformity of the low power plasma system has met the preset value, the low power plasma system is able to perform a pretreatment process on the barrier 24 and the gate material 253 and/or the separating layer 251 of HEMT to repair dangling bonds on the barrier 24 and the gate material 253 and/or the separating layer 251 on the substrate 21. For example, when the difference sheet resistance value Rsd of each region 311 of the testing substrate 31 is similar, or the different between the largest value of the difference sheet resistance value Rsd and the smallest value of the difference sheet resistance value Rsd is smaller than a threshold value, it can be determined that the uniformity of the low power plasma system has met the preset value.

In actual application, the testing pretreatment process may be performed on a plurality of testing substrates 31 through the low power plasma system, and the uniformity of the testing passivation on each batch of testing substrates 31 can be analyzed to further confirm the stability and uniformity of the low power plasma system.

As shown in FIG. 5, after determining that the uniformity and/or the stability of the low power plasma system reach the preset value, the low power plasma system is suitable for performing the pretreatment process on a semiconductor device to repair dangling bond of the semiconductor device. For example, the low power plasma system performs the pretreatment process to repair dangling bonds on the surface of the barrier 24, the gate material 253 and/or the separating layer 251 of HEMT. Then, the ALD process is performed to form a passivation 281 on the surface of the barrier 24, the gate material 253 and/or the separating layer 251 of HEMT. In one embodiment of the invention, the process conditions of the testing pretreatment process for the testing substrate 31 and the process conditions of the pretreatment process for the substrate 21 may be the same. In other embodiments, process conditions of the testing pretreatment process and the pretreatment process may be different.

As shown in FIG. 6, after completing the setting of the passivation 281, an insulating layer 283 may be formed on the surface of the passivation 281. Thereafter, a partial area of the insulating layer 283, a passivation 281 and a barrier 24 may be etched to form a plurality of etched areas, and a source material 291 and a drain material 293 may be formed in the etched areas, wherein the source material 291 and the drain material 293 are connected to the channel 23.

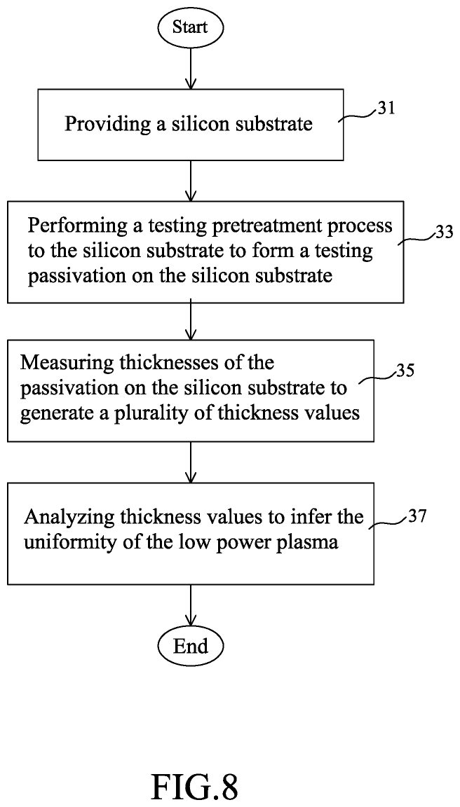

As shown in FIG. 8, a silicon substrate is provided. For example, the testing substrate is the silicon substrate, as step 31. The silicon substrate is placed in a chamber, and a testing pretreatment process is performed to the surface of the silicon substrate through the low power plasma system to form a testing passivation on the surface of the silicon substrate, as step 33. For example, the process conditions of the low power plasma system performing the testing pretreatment process may be: nitrogen gas with a gas flow rate of 50 sccm, power less than 50 W and pretreatment time of 6 hours, and the testing passivation of silicon nitride is formed on the surface of the titanium film. The gas flow rate, power and pretreatment time of the above-mentioned low power plasma system are only one embodiment of the invention, and are not limitations the invention.

After completing the testing pretreatment process on the silicon substrate, the silicon substrate will be taken out of the chamber to measures the thicknesses of the testing passivation to generate a plurality of thickness values, as step 35. For example, the silicon substrate and/or the testing passivation is divided into a plurality of regions, and an ellipsometer measures thickness of the testing passivation in each region. Thereafter, by analyzing the thickness values, the uniformity of the testing passivation on the silicon substrate can be known, and then the uniformity of the low power plasma system can be inferred, as step 37.

In actual application, the thickness values of all regions can be compared with each other, or a thickness distribution diagram of the testing passivation on the silicon substrate can be made to determine whether the uniformity of the testing passivation and low power plasma system meets the preset value.

After determining that the uniformity of the low power plasma system has met the preset value, the low power plasma system is able to perform a pretreatment process on the barrier 24 and the gate material 253 and/or the separating layer 251 of HEMT to repair dangling bonds on the barrier 24 and the gate material 253 and/or the separating layer 251 on the substrate 21. For example, when the difference of thickness value of each region of the silicon substrate is similar, or the different between the largest value of the thickness value and the smallest value of the thickness value is smaller than a threshold value, it can be determined that the uniformity of the low power plasma system has met the preset value.

The above description is only a preferred embodiment of this disclosure, and is not intended to limit the scope of this disclosure. Modifications should be included within the scope of the patent application of this disclosure.

What is claimed is:

1. A low power plasma system monitor method, comprising:
providing a testing substrate, wherein a surface of the testing substrate has a metal film;
measuring sheet resistances of the metal film on the testing substrate, and generating a plurality of first sheet resistance values;
performing a testing pretreatment process on the metal film of the testing substrate by a low power plasma system, and forming a testing passivation on the metal film;
measuring the sheet resistances of the testing passivation on the testing substrate, and generating a plurality of second sheet resistance values; and
analyzing the plurality of first sheet resistance values and the plurality of second sheet resistance values to obtain uniformity of the low power plasma system.

2. The low power plasma system monitor method according to claim 1, further comprising: performing a deposition process on the testing substrate to form the metal film on the testing substrate.

3. The low power plasma system monitor method according to claim 2, further comprising: performing the testing pretreatment process on the metal film of the testing substrate by the low power plasma, in an interval time after completing the deposition process on the testing substrate.

4. The low power plasma system monitor method according to claim 3, wherein the interval time is less than 4 hours.

5. The low power plasma system monitor method according to claim 1, further comprising: dividing the testing substrate into a plurality of regions, and measuring the sheet resistances of the plurality of regions on the testing substrate respectively, to generate the plurality of first sheet resistance values.

6. The low power plasma system monitor method according to claim 5, further comprising: measuring the sheet resistances of the plurality of regions on the testing substrate that has performed the testing pretreatment process to generate the plurality of second sheet resistance values.

7. The low power plasma system monitor method according to claim 6, further comprising: calculating differences between the first sheet resistance values and the second sheet resistance values in the plurality of regions respectively to generate a plurality of difference sheet resistance values.

8. The low power plasma system monitor method according to claim 7, further comprising: judging uniformity of the testing passivation on the metal film of the testing substrate according to the plurality of difference sheet resistances in the plurality of regions.

9. The low power plasma system monitor method according to claim 8, further comprising: judging uniformity of the low power plasma system according to uniformity of the testing passivation.

10. The low power plasma system monitor method according to claim 8, further comprising: judging that a difference between the largest value of the plurality of difference sheet resistance and the smallest value of the plurality of difference sheet resistance is less than a threshold value.

11. The low power plasma system monitor method according to claim 10, further comprising: performing a pretreatment process to a semiconductor device by the low power plasma system.

12. The low power plasma system monitor method according to claim 1, wherein a thickness of the metal film on the testing substrate is less than 100 angstroms.

13. The low power plasma system monitor method according to claim 1, wherein a power of the low power plasma system is less than 50 W.

14. A low power plasma system monitor method, comprising:
providing a silicon substrate;
performing a testing pretreatment process on the silicon substrate by a low power plasma system, and forming a testing passivation on the silicon substrate;
measuring thicknesses of the testing passivation on the silicon substrate, and generating a plurality of thickness values; and
analyzing the plurality of thickness values to obtain uniformity of the low power plasma system.

15. The low power plasma system monitor method according to claim 14, further comprising: dividing the silicon substrate into a plurality of regions, and measuring the thicknesses of the testing passivation on the plurality of regions of the silicon substrate respectively, to generate the plurality of thickness values.

16. The low power plasma system monitor method according to claim 15, further comprising:
judging uniformity of the testing passivation on the silicon substrate according to the plurality of thickness values in the plurality of regions; and
judging uniformity of the low power plasma system according to uniformity of the testing passivation.

17. The low power plasma system monitor method according to claim 15, further comprising: measuring thicknesses of the testing passivation on the silicon substrate by an ellipsometer, and generating a plurality of thickness values.

18. The low power plasma system monitor method according to claim 15, further comprising: judging that a difference between the largest value of the plurality of thickness values and the smallest value of the plurality of thickness values is less than a threshold value.

19. The low power plasma system monitor method according to claim 18, further comprising: performing a pretreatment process to a semiconductor device by the low power plasma system.

20. The low power plasma system monitor method according to claim 14, wherein a power of the low power plasma system is less than 50 W.
